(19) United States
(12) Patent Application Publication
(10) Pub. No.: US 2009/0061616 A1
(43) Pub. Date: Mar. 5, 2009

(54) METHOD FOR FABRICATING SEMICONDUCTOR DEVICE

(76) Inventor: Hyun Park, Jincheon-gun (KR)

Correspondence Address: SHERR & VAUGHN, PLLC, 620 HERNDON PARKWAY, SUITE 200, HERNDON, VA, 20170, US

(21) Appl. No.: 12/194,568

(22) Filed: Aug. 20, 2008

(30) Foreign Application Priority Data
Aug. 31, 2007 (KR) 10-2007-0088470

(51) Int. Cl. H01L 21/768

(52) U.S. Cl. 438/627; 257/E21.583

(57) ABSTRACT

A method for fabricating semiconductor device capable of minimizing hillocks and voids. The method includes subjecting an interlayer dielectric having a multi-protective dielectric structure including a first barrier metal layer and a first copper line to a plurality of NH₃ treatment processes, forming a capping film on the first copper line, and planarizing the capping film via chemical mechanical polishing (CMP).

The present application claims priority under 35 U.S.C. 119 to Korean Patent Application No. 10-2007-0088470 (filed on Aug. 31, 2007), which is hereby incorporated by reference in its entirety.

### BACKGROUND

Aspects of semiconductor fabricaton technology have focused on obtaining devices having ultra high integration. In the fabrication of semiconductor devices, metals such as aluminum (Al), aluminum alloys and tungsten (W) are generally used for metal lines. However, with the trend towards high-integration, semiconductor devices have decreased melting points and increased specific resistance. For this reason, currently used metals cannot be applied to ultra high-integration semiconductors devices. Accordingly, there is an increasing demand for development of alternative metal line materials. Examples of these alternative materials include metals exhibiting superior conductivity, such as copper (Cu), gold (Au), silver (Ag), cobalt (Co), chrome (Cr) and nickel (Ni) and the like. Of these, copper and copper alloys have been widely used since they have a low specific resistance, exhibit superior electromigration (EM) and stressmigration (SM) reliability and have low preparation costs.

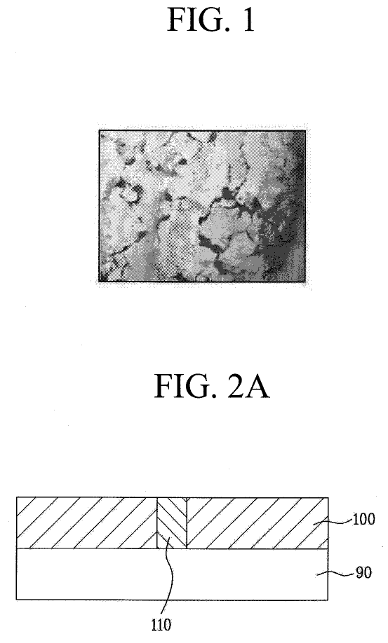

Since copper lines can reduce RC time delay due to resistivity lower than aluminum lines, they are being used for devices having a design rule of 0.13 μm or lower. Copper lines have tenfold thermal expansion coefficients of dielectric films, and thus, are rapidly expanded at temperatures above a specific level used for semiconductor processes. For this reason, compressive stress is applied to the copper lines. High compressive stress causes creation of small hill-like structures called “hillocks” on copper lines. As illustrated in example FIG. 1, hillocks make metal line residues left after chemical mechanical polishing (CMP). These residues cause short-circuits between metal lines and voids, thus negatively affecting process reliability.

### SUMMARY

Embodiments relate to a method for fabricating a semiconductor device that reduces generation of hillocks and voids.

Embodiments relate to a method for fabricating a semiconductor device that can include at least one of the following steps: providing an interlayer dielectric having a multi-protective dielectric structure including a first barrier metal layer and a first copper line layer planarized by chemical mechanical polishing (CMP); and then subjecting the interlayer dielectric to an NH₃ treatment process; and then forming a capping film for copper diffusion prevention on and/or over the interlayer dielectric including the first copper line layer; and then planarizing the capping film using chemical mechanical polishing (CMP).

Embodiments relate to a method for reducing the generation of hillocks on the surface of a metal line that can include at least one of the following steps: sequentially performing a plurality of NH₃ treatment processes on the metal line; and then forming a capping film over the metal line and then increasing the thickness of the capping film until it corresponds to the thickness of the hillocks; and then planarizing the capping film by performing a chemical mechanical polishing process.

Embodiments relate to a method for reducing the generation of hillocks on the surface of a copper line that can include at least one of the following steps: forming a copper layer as the metal line in a first dielectric layer; and then sequentially performing a plurality of NH₃ treatment processes on the first copper line; and then forming a capping film over the first copper line such that the thickness of the capping film is increased until it corresponds to the thickness of the hillocks; and then planarizing the capping film; and then sequentially forming a second, third and fourth dielectric films over the capping film; and then forming a trench in the third and fourth dielectric films by performing an etching process; and then forming a second copper layer as a second metal line in the trench.

### DRAWINGS

Example FIG. 1 illustrates formation of hillocks in a semiconductor device.

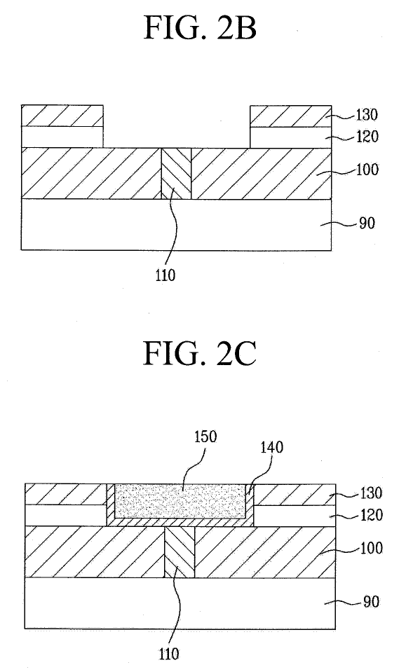

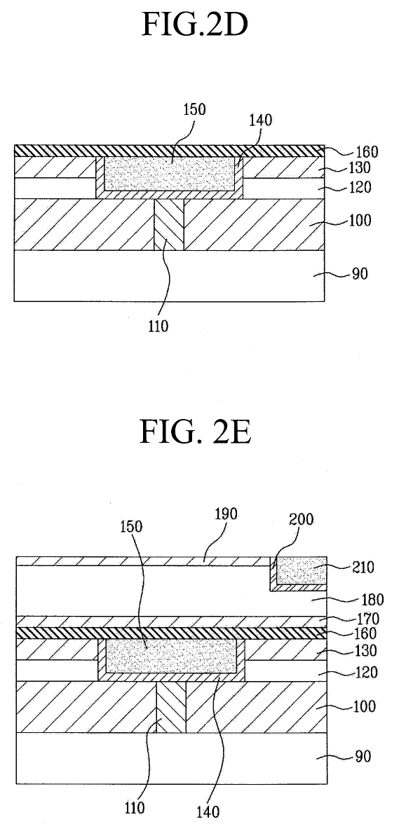

Example FIGS. 2A to 2E illustrates a method of fabricating a semiconductor device in accordance with embodiments.

### DESCRIPTION

As illustrated in example FIG. 2A, first protective dielectric film 100 is deposited on and/or over semiconductor substrate 90, and an exposure process is performed in order to form a photoresist for forming a contact hole. First protective dielectric film 100 may be made of SiH₄. The photoresist is formed by exposing the photoresist film coated on and/or over semiconductor substrate 90 to exposure equipment using a predetermined exposure mask, baking the resulting photoresist in baking equipment and removing the exposed photoresist using a predetermined developing solution. After the exposure, first protective dielectric film 100 is etched using the photoresist as a mask to form a contact hole. Plug 110 composed of a metal such as tungsten is then formed in the contact hole.

As illustrated in example FIG. 2B, second protective dielectric film 120 and third protective dielectric film 130 are sequentially deposited on and/or over first protective insulating layer 100 including tungsten plug 110. Second protective dielectric film 120 may be formed of fluorosilicate glass (FSG) and third protective dielectric film 130 may be formed of silane (SiH₄). After the deposition of second protective dielectric film 120 and third protective dielectric film 130, an exposure process is performed to form a photoresist for forming a trench. Second protective dielectric film 120 and third protective dielectric film 130 are dry-etched using the photoresist as a mask to form a trench exposing plug 110.

As illustrated in example FIG. 2C, after the photoresist is removed, first barrier metal 140 and first copper line layer 150 are formed over the entire surface of semiconductor substrate 90 including the trench. First copper line layer 150 is then planarized via chemical mechanical polishing (CMP) such that the surface of third protective dielectric film 130 is exposed. First barrier metal 140 may be formed of Ta/TaN. An oxide layer such as cupric oxide (CuO) formed on and/or over the exposed first copper line layer 150 is reduced to pure copper by performing a NH₃ treatment process that includes a plurality of steps. The NH₃ treatment process may be carried out by perfoming respective steps for a predetermined period of time. For example, the NH₃ treatment process may be composed of two steps including a primary step performed for 7 seconds and a secondary step performed for 8 seconds. Alternatively, the NH₃ treatment process may be composed of three steps in which each step is performed for 5 seconds. As a result, it is possible to minimize the thickness of hillocks created on the surface of first copper line layer 150.

As illustrated in example FIG. 2D, capping film 160 for preventing diffusion of copper may then be formed on and/or over the entire surface of semiconductor substrate 90 including first copper line layer 150. Capping film 160 may be formed at 350 to 400° C. using at least one of silicon carbide (SiC), silicon carbon nitride (SiCN) and fluorine-doped silicon oxide (SiOF). In addition, the thickness of capping film 160 may be increased until it corresponds to the thickness of the hillock. Subsequently, capping film 160 is planarized via chemical mechanical polishing.

As illustrated in example FIG. 2E, fourth protective dielectric film 170, fifth protective dielectric film 180 and sixth protective dielectric film 190 may then be sequentially deposited on and/or over capping film 160. Fifth protective dielectric film 180 and sixth protective dielectric film 190 may then be subjected to exposure and etching to form a trench. Second barrier metal 200 and second copper line layer 210 are then formed on and/or over the entire surface of sixth protective dielectric film 190 including the trench. Fourth protective dielectric film 170 and sixth protective dielectric film 190 may be formed of SiH₄ and fifth protective dielectric film 180 may be formed of FSG. Capping film 160 is increased to a thickness not smaller than the thickness of hillocks formed on copper line 150 and is then planarized via CMP, thereby minimizing the thickness of hillocks via heat treatment during deposition of fourth protective dielectric film 170, fifth protective dielectric film 180 and sixth protective dielectric film 190. As a result, short-circuit between lines caused by first barrier metal layer 140 residues can be reduced. In addition, occurrence of voids can be prevented by controlling the thickness of hillocks.

As apparent from the afore-going, the method of fabricating for a semiconductor device has at least the following advantages. First, a NH₃ plasma treatment process is performed through a plurality (i.e., two or three) steps, thereby minimizing hillocks on the copper line. Second, the capping film for copper diffusion prevention may deposited on and/or over the copper line to a thickness not smaller than the thickness of hillocks formed on the copper line and then planarized, thereby minimizing the hillock thickness via heat treatment during deposition of the IDL layer and reducing short-circuit caused by barrier metal layer residues. Third, occurrence of voids can be prevented by controlling the thickness of hillocks formed on the contact hole.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for fabricating a semiconductor device comprising:
forming a first dielectric film having a first metal layer formed therein over a semiconductor substrate; and then
sequentially forming first and second dielectric film over the first dielectric film and then forming a trench exposing the conductor by performing a first etching process on the first and second dielectric film; and then
sequentially forming a second metal layer over the first metal layer and a third metal layer as a metal line over the second metal layer and filling the trench; and then
subjecting at least the third metal layer to an NH₃ treatment process; and then
forming a capping film on the third dielectric film including the third metal layer.

2. The method of claim 1, wherein the first dielectric film is formed of silane, the second dielectric film is formed of flurosilicate glass and the third dielectric film is formed of silane.

3. The method of claim 1, further comprising, after forming the capping layer:
sequentially forming a fourth dielectric film, a fifth dielectric film and a sixth dielectric film on the capping film; and then
performing a second etching process on the fifth and sixth dielectric films to form a trench; and then
forming a fourth metal layer and a fifth metal layer as a second metal line over the fourth metal layer and in the trench.

4. The method of claim 3, wherein the fourth dielectric film is formed of silane, the fifth protective dielectric film is formed of phosphosilicate glass and the sixth dielectric film is formed of silane.

5. The method of claim 1, wherein the capping film is formed of at least one of silicon carbide (SiC), silicon carbon nitride (SiCN) and fluorine-doped silicon oxide (SiOF).

6. The method of claim 1, wherein the capping film is formed at a temperature in a range of between 350 to 400° C.

7. The method of claim 1, wherein forming the capping film comprises increasing the thickness of the capping film until the thickness corresponds to the thickness of hillocks formed on the metal line.

8. The method of claim 1, wherein the NH₃ treatment process comprises a primary step performed for 7 seconds and a secondary step performed for 8 seconds.

9. The method of claim 1, wherein the NH₃ treatment process comprises sequentially performing three steps for 5 seconds each.

10. The method of claim 1, wherein the second metal layer is formed of Ta/TaN.

11. The method of claim 1, further comprising, after forming the capping layer:
planarizing the capping film via chemical mechanical polishing.

12. A method for reducing the generation of hillocks on the surface of a metal line, said method comprising:
sequentially performing a plurality of NH₃ treatment processes on the metal line; and then
forming a capping film over the metal line and then increasing the thickness of the capping film until it corresponds to the thickness of the hillocks; and then
planarizing the capping film by performing a chemical mechanical polishing process.

13. The method of claim 12, wherein sequentially performing the plurality of NH₃ treatment processes comprises:
sequentially performing a first NH₃ treatment process for a first predetermined time period and then a second NH₃ treatment process for a second predetermined time period.

14. The method of claim 13, wherein the first predetermined time period is less than the second predetermined time period.

15. The method of claim 13, wherein the first predetermined time period is 7 seocnds and the second predetermined time period is eight seconds.

16. The method of claim 12, wherein sequentially performing the plurality of NH₃ treatment processes comprises:
sequentially performing a first NH₃ treatment process for a first predetermined time period a second NH₃ treatment process for a second predetermined time period and then a third NH₃ treatment process for a third predetermined time period.

17. The method of claim 16, wherein the first, second and third predetermined time periods are substantially the same.

18. The method of claim 16, wherein the first, second and third predetermined time periods are 5 seconds each.

19. A method for reducing the generation of a hillock on the surface of a metal line, said method comprising:
forming a copper layer as the metal line in a first dielectric layer; and then
sequentially performing a plurality of NH₃ treatment processes on the first copper line; and then
forming a capping film over the first copper line, wherein forming the capping film includes increasing the thickness of the capping film until it corresponds to the thickness of the hillock; and then
planarizing the capping film; and then
sequentially forming a second, third and fourth dielectric films over the capping film; and then
forming a trench in the third and fourth dielectric films by performing an etching process; and then
forming a second copper layer as a second metal line in the trench.

20. The method of claim 19, wherein sequentially forming the second, third and fourth dielectric films comprises conducting a heat treatment process.
